(19) United States
(12) Patent Application Publication
(10) Pub. No.: US 2023/0011694 A1
(43) Pub. Date: Jan. 12, 2023

(54) SEMICONDUCTOR PACKAGE HAVING PACKAGE HOUSING IN ENGRAVED SURFACE FORM AND METHOD OF MANUFACTURING THE SAME

(71) Applicant: JMJ Korea Co., Ltd., Bucheon-si (KR)

(72) Inventor: Yun Hwa CHOI, Bucheon-si (KR)

(73) Assignee: JMJ Korea Co., Ltd., Bucheon-si (KR)

(21) Appl. No.: 17/848,390

(22) Filed: Jun. 24, 2022

(30) Foreign Application Priority Data
Jul. 9, 2021 (KR) 10-2021-0090542

(51) Int. Cl. H01L 23/433; H01L 25/07; H01L 23/00; H01L 21/48; H01L 21/56

(52) U.S. Cl. CPC H01L 23/4334; H01L 25/072; H01L 24/73; H01L 24/32; H01L 24/16; H01L 21/4882; H01L 21/565; H01L 24/48; H01L 2224/32225; H01L 2224/16225; H01L 2224/48225; H01L 2224/73265; H01L 2224/73253; H01L 2224/73203; H01L 2224/73215; H01L 2224/73207; H01L 2924/35121; H01L 2224/16055; H01L 2924/1815; H01L 2924/182; H01L 2924/183; H01L 2924/16251; H01L 2924/16196; H01L 2924/16315; H01L 2924/1632; H01L 2924/1631

(57) ABSTRACT

Provided is a semiconductor package having a package housing in an engraved surface form and a method of manufacturing the same, wherein the semiconductor package includes: at least one substrate on which at least one semiconductor chip is installed; at least one terminal lead electrically connected to the substrates; electrical connectors for connecting the semiconductor chips to the substrates or the terminal leads; a package housing covering the semiconductor chips, the electrical connectors, and the at least one substrate; at least one stopper which is formed of a material same as that of the package housing, is higher by a certain height than exposed surfaces of the substrates, is disposed on the exposed surfaces of the substrates, or covers at least a part of the exposed surfaces; and at least one heat sink transmitting heat from the semiconductor chips and radiating heat, wherein the at least a part of the exposed surfaces of the at least one substrate is formed on the upper surface, the lower surface, or the upper and lower surfaces of the package housing and the exposed surfaces of the at least one substrate are joined to the heat sinks by using heat transfer connectors interposed therebetween. Accordingly, the full thickness of the heat transfer connectors may be uniformly maintained.

### CROSS-REFERENCE TO RELATED PATENT APPLICATION

This application claims the benefit of Korean Patent Application No. 10-2021-0090542, filed on Jul. 9, 2021, in the Korean Intellectual Property Office, the disclosure of which is incorporated herein in its entirety by reference.

### BACKGROUND OF THE INVENTION

### 1. Field of the Invention

The present invention relates to a semiconductor package having a package housing in an engraved surface form and a method of manufacturing the same, wherein in the semiconductor package, a thickness of a heat transfer connector used to join and transfer heat to a heat sink may be adjusted through a stopper, which is engraved using a laser, and uniformly maintained to suppress delamination and to improve heat transfer efficiency.

### 2. Description of the Related Art

As well known in the art, electrical and electronic components, in particular, semiconductor components, generate heat while they operate so that a heat sink is used to prevent overheating and to maintain their performances.

In particular, semiconductor components applied in a high-power application field prevent overheating by using a heat sink which circulates a coolant. Here, the heat sink includes a cooling part member for contacting the circulating coolant so as to cool heat transferred from a semiconductor component to the cooling part member.

FIGS. 1A and 1B are a cross-sectional view of a conventional semiconductor package. Referring to FIGS. 1A and 1B, a sealing member is molded to cover a lower substrate 21 and an upper substrate 22 respectively by using a lower mold (not illustrated) and an upper mold (not illustrated) and a package housing 30 is formed. Here, over molding of the sealing member is generated due to an error of the mold.

In order to bond a heat sink 50 to an exposed surface A of the lower substrate 21 or the upper substrate 22 by using an adhesive 40, a grinding wheel 11 is used to remove the over-molded sealing member disposed at the upper part of the lower substrate 21 or the upper substrate 22.

However, when the sealing member is removed by the grinding wheel as described above, consumption of the sealing member increases and a metal layer forming the substrate is cut while grinding the sealing member by the grinding wheel so that an insulating layer such as ceramic may be cracked. Here, when a thickness of the metal layer grows in order to prevent such a crack, costs may increase. Also, metal particles generated after grinding remain between the sealing member so that problems on insulation voltage may occur and delamination may be generated due to stress on the semiconductor package.

In addition, when the adhesive is coated for bonding to the heat sink, a gap between the surface of the substrate and the sealing member is uneven and thus, a thickness of the adhesive, in particular, the thickness at both ends of the adhesive may not be uniform. Accordingly, heat transfer efficiency is lowered and delamination is generated.

### SUMMARY OF THE INVENTION

The present invention provides a semiconductor package having a package housing in an engraved surface form and a method of manufacturing the same, wherein in the semiconductor package, a thickness of a heat transfer connector used to join and transfer heat to a heat sink may be adjusted through a stopper, which is engraved using a laser, and uniformly maintained to suppress delamination and to improve heat transfer efficiency.

According to an aspect of the present invention, there is provided semiconductor package having a package housing in an engraved surface form including: at least one substrate on which at least one semiconductor chip is installed; at least one terminal lead electrically connected to the substrates; electrical connectors for connecting the semiconductor chips to the substrates or the terminal leads; a package housing covering the semiconductor chips, the electrical connectors, and the at least one substrate; at least one stopper which is formed of a material same as that of the package housing, is higher by a certain height than exposed surfaces of the substrates, is disposed on the exposed surfaces of the substrates, or covers at least a part of the exposed surfaces; and at least one heat sink transmitting heat from the semiconductor chips and radiating heat, wherein the at least a part of the exposed surfaces of the at least one substrate is formed on the upper surface, the lower surface, or the upper and lower surfaces of the package housing and the exposed surfaces of the at least one substrate are joined to the heat sinks by using heat transfer connectors interposed therebetween.

According to another embodiment of the present invention, there is provided a semiconductor package having a package housing in an engraved surface form including: at least one substrate on which at least one semiconductor chip is installed; at least one terminal lead electrically connected to the substrates; electrical connectors for connecting the semiconductor chips to the substrates or the terminal leads; a package housing covering the semiconductor chips, the electrical connectors, and the at least one substrate; at least one stopper which is formed of a material same as that of the package housing, is higher by a certain height than exposed surfaces of the substrates, and is not overlapped with the exposed surfaces of the substrates; and at least one heat sink transmitting heat from the semiconductor chips and radiating heat, wherein the at least a part of the exposed surfaces of the at least one substrate is formed on the upper surface, the lower surface, or the upper and lower surfaces of the package housing and the exposed surfaces of the at least one substrate are joined to the heat sinks by using heat transfer connectors interposed therebetween.

The substrates may be metal substrates or include at least one insulating layer.

The height of the stoppers may be 1 μm through 1 mm.

The stoppers may be formed to be high in the form of at least any one plane including a circle, a quadrangle, and a polygon.

The at least one stopper may be formed by partially engraving the surface of the package housing using a laser.

The height of the at least one stopper may be determined by the partial surface of the package housing which is not engraved.

The electrical connectors may be formed of any one single metal including Au, Ag, Al, and Cu or an alloy containing 50 weight % or more of any one or more metal including Au, Ag, Al, and Cu.

The electrical connectors may be conductive spacers in a hexahedral or a cylindrical form.

One side of the spacer may be electrically joined to the semiconductor chip on a first substrate using a conductive adhesive and the other side of the spacer may be electrically joined to a second substrate using a conductive adhesive.

The electrical connectors may be electrically connected between the at least one semiconductor chip and the substrates.

The semiconductor chips may be installed on an upper substrate or a lower substrate.

The stoppers may include at least one spherical grain or at least one round groove on the wall thereof.

The diameter of the grains or the depth of the round grooves may be 1 μm through 100 μm.

The heat sink may include at least one metal layer or at least one ceramic layer on one surface thereof.

The thickness of the heat transfer connector interposed between one surface of the heat sink and the exposed surface of the at least one substrate may be 1 μm through 1 mm.

The heat transfer connector may have thermal conductivity of 1 W/m-k through 400 W/m-k.

The heat transfer connectors may be trapped by 60% or more in the stoppers, the exposed surfaces of the substrates, and the one surfaces of the heat sinks.

The at least one semiconductor chip may be structurally connected to one surface of the lower substrate by using an adhesive, the at least one stopper may not be formed on the other surface of the lower substrate, the at least one stopper may be formed on one surface of the upper substrate, and the other surface of the upper substrate may be electrically connected to the semiconductor chips through the electrical connectors.

The at least one semiconductor chip may be structurally connected to one surface of the lower substrate by using an adhesive, the at least one stopper may be formed on the other surface of the lower substrate, the at least one stopper may be formed on one surface of the upper substrate, and the other surface of the upper substrate may be electrically connected to the semiconductor chips through the electrical connectors.

According to another aspect of the present invention, there is provided a method of manufacturing a semiconductor package having a package housing in an engraved surface form including: preparing a lower substrate and the upper substrate to which at least one semiconductor chip is to be installed, electrical connectors, and at least one terminal lead;

structurally connecting the lower substrate, the upper substrate, the semiconductor chips, and the electrical connectors by using conductive adhesives; forming a package housing to cover the semiconductor chips, the electrical connectors, the entire surfaces of the lower and upper substrates being installed, and at least a part of the exposed surfaces of the lower substrate and the upper substrate; partially engraving the surface of the package housing by using a laser to form stoppers to be higher by a certain height than exposed surfaces of the lower substrate or the upper substrate; and joining the exposed surfaces of the at least one substrate to heat sinks by using heat transfer connectors.

The height of the stoppers may be 1 μm through 1 mm.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B are a cross-sectional view of a conventional semiconductor package;

FIG. 2 is a cross-sectional view of a semiconductor package having a package housing in an engraved surface form according to an embodiment of the present invention;

FIG. 3 illustrates a structure of a stopper on an upper part of a substrate included in the semiconductor package of FIG. 2 according to an embodiment of the present invention;

FIG. 4 illustrates a structure of a stoppers on an upper part of a substrate included in the semiconductor package of FIG. 2 according to another embodiment of the present invention;

FIG. 5 is a cross-sectional view of a semiconductor package to which a heat sink is joined;

FIGS. 6A and 6B are scanning electron microscope (SEM) photographs of a side of a stopper included in a semiconductor package having a package housing in an engraved surface form according to the present invention; and

FIGS. 7A, 7B, 7C and 7D illustrate a method of manufacturing a semiconductor package having a package housing in an engraved surface form according to another embodiment of the present invention.

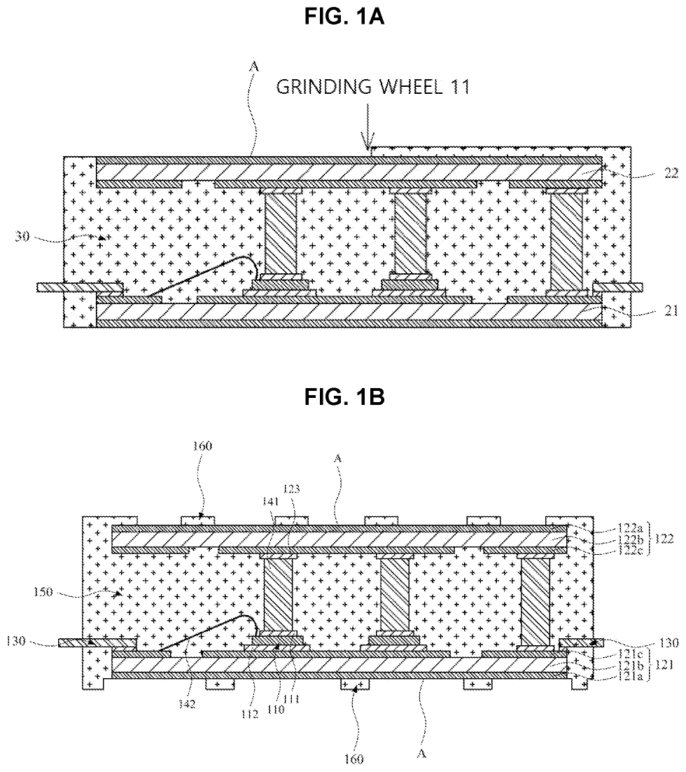

### DETAILED DESCRIPTION OF THE INVENTION

Hereinafter, the embodiments of the present invention will be described in more detail with reference to the accompanying drawings.

The present invention provides a semiconductor package having a package

housing in an engraved surface form including a stopper 160 overlapped with an exposed surface A of substrates 121 and 122 included in a package housing 150 according to an embodiment of the present invention, a semiconductor package having a package housing in an engraved surface form including the stopper 160 which is not overlapped with the exposed surface A of the substrates 121 and 122 according to another embodiment of the present invention, and a method of manufacturing a semiconductor package having a package housing in an engraved surface form in which the stopper 160 is formed by being engraved using a laser 10.

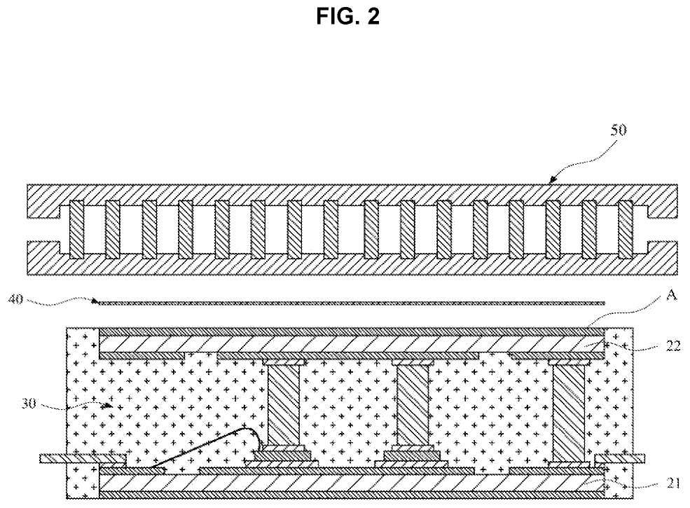

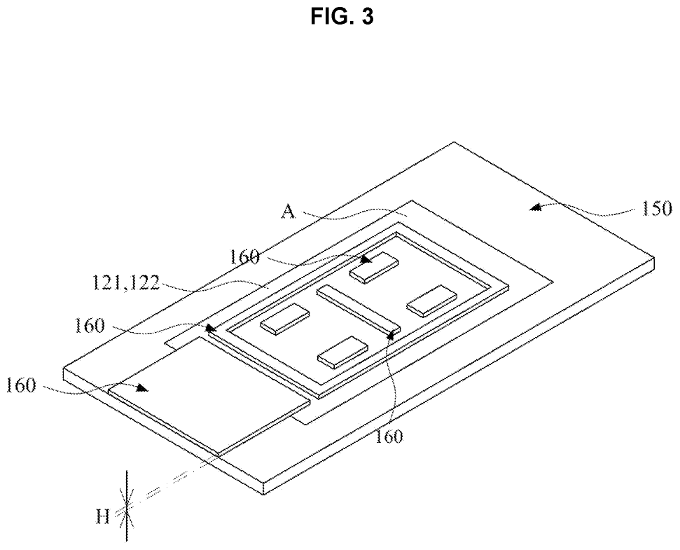

Referring to FIGS. 2 and 3, the semiconductor package having a package housing in an engraved surface form according to an embodiment of the present invention includes one or more substrates 121 and 122 on which at least one semiconductor chip 110 is installed, one or more terminal leads 130 electrically connected to the substrates 121 and 122, electrical connectors for connecting the semiconductor chips 110 to the substrates 121 and 122 or the terminal leads 130, the package housing 150 covering the semiconductor chips 110, the electrical connectors, and one or more substrates 121 and 122, at least one stopper 160 which is formed of a material same as that of the package housing 150, is higher by a certain height than exposed surfaces A of the substrates 121 and 122, is disposed on the exposed surfaces A of the substrates 121 and 122, or covers at least a part of the exposed surfaces A of the substrates 121 and 122, and at least one heat sink 170 transmitting heat from the semiconductor chips 110 and radiating heat. Here, the at least a part of the exposed surfaces A of one or more substrates 121 and 122 is formed on the upper surface, the lower surface, or the upper and lower surfaces of the package housing 150, and the exposed surface A of one or more substrates 121 and 122 is joined to the heat sinks 170 by using heat transfer connectors 171 interposed therebetween. Accordingly, the full thickness of the heat transfer connectors 171 may be uniformly maintained.

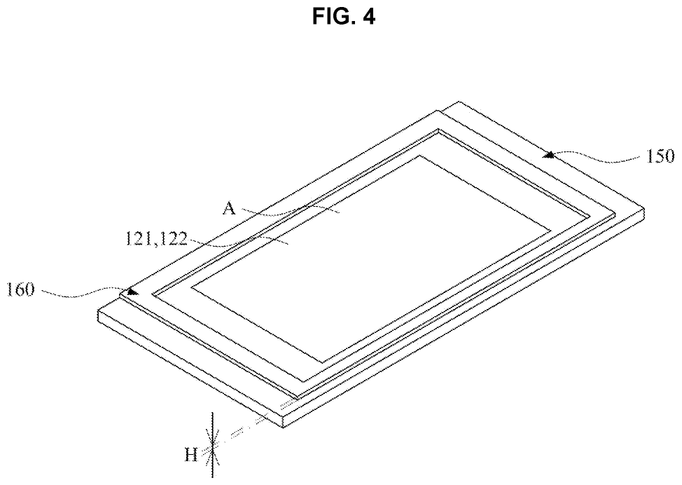

Referring to FIGS. 2 and 4, the semiconductor package having a package housing in an engraved surface form according to another embodiment of the present invention includes one or more substrates 121 and 122 on which at least one semiconductor chip 110 is installed, one or more terminal leads 130 electrically connected to the substrates 121 and 122, electrical connectors for connecting the semiconductor chips 110 to the substrates 121 and 122 or the terminal leads 130, the package housing 150 covering the semiconductor chips 110, the electrical connectors, and one or more substrates 121 and 122, at least one stopper 160 which is formed of a material same as that of the package housing 150, is higher by a certain height than exposed surfaces A of the substrates 121 and 122, and is not overlapped with the exposed surfaces A of the substrates 121 and 122, and at least one heat sink 170 transmitting heat from the semiconductor chips 110 and radiating heat. Here, the at least a part of the exposed surfaces A of one or more substrates 121 and 122 is formed on the upper surface, the lower surface, or the upper and lower surfaces of the package housing 150, and the exposed surfaces A of one or more substrates 121 and 122 are joined to the heat sink 170 by using the heat transfer connectors 171 interposed therebetween. Accordingly, the full thickness of the heat transfer connectors 171 may be uniformly maintained.

Firstly, one or more substrates are formed to install at least one semiconductor chip 110 thereon.

The substrates may be metal substrates or include at least one insulating layer formed of ceramic. As illustrated in FIG. 2, the substrate may have a stacked structure including at least one metal layer 121a and 122a, insulating layers 121b and 122b disposed on the metal layers 121a and 122a, and at least one metal layers 121c and 122c having a metal pattern formed on the insulating layers 121b and 122b.

For example, the substrate may be exposed to one surface or both surfaces of the package housing 150 according to a single sided board or a both sided board, and include the lower substrate 121 on which the semiconductor chip 110 is installed, and the upper substrate 122 spaced apart from the lower substrate 121. Also, the semiconductor chips 110 and the upper substrate 122 may be electrically connected to each other by a surface connection method using a spacer 141 which is an electrical connector, and an adhesive 111 may be filled between the semiconductor chip 110 and the electrical connector.

In addition, the semiconductor chips 110 may be installed on the lower substrate 121 or the upper substrate 122 and may be a diode, a thyristor, an Insulated Gate Bipolar Transistor (IGBT), or a Metal-Oxide-Semiconductor Field-Effect Transistor (MOSFET). In particular, the semiconductor chips 110 may be used in devices used to convert or control electricity such as an inverter, a converter, or an On Board Charger (OBC) and thereby, convert electricity into specific current, specific voltage, or specific frequency.

Next, one or more terminal leads 130 are included to electrically connect to the lower substrate 121 and/or the upper substrate 122 and are exposed to the outside of the package housing 150 to apply an electrical signal to the semiconductor chips 110.

Here, the terminal leads 130 may include a metal containing 80 weight % or more of Cu or 60 weight % or more of Al.

Next, the electrical connectors electrically connect the semiconductor chips 110 to the substrates 121 and 122 or the terminal leads 130, and is formed of any one single metal including Au, Ag, Al, and Cu or an alloy containing 50 weight % or more of any one or more metal including Au, Ag, Al, and Cu.

For example, as illustrated in FIG. 2, the electrical connectors may be the spacers 141 which is conductive and in a hexahedral or a cylindrical form, and electrically connect the semiconductor chip 110 disposed on the lower substrate 121 or the upper substrate 122 to the upper substrate 122 or the lower substrate 121. Also, the electrical connectors may be metal wires 142 or metal clips electrically connecting the semiconductor chip 110 to the terminal lead 130 so as to enable electrical connection between the at least one semiconductor chip 110 and the substrates 121 and 122.

Here, one side of the spacer 141 may be electrically joined to the semiconductor chip 110 on a first substrate, that is, the lower substrate 121, using the conductive adhesive 111 and the other side of the spacer 141 may be electrically joined to a second substrate, that is, the upper substrate 122, using a conductive adhesive 123.

Next, the package housing 150 is an insulator for protecting a semiconductor circuit which covers and protects the semiconductor chips 110, the electrical connectors, and one or more substrates 121 and 122 and may be formed of an Epoxy Molding Compound (EMC). However, instead of an epoxy-based material, the package housing 150 may be formed of a composite material such as PolyPhenylene Sulfide (PPS) or PolyButylene Terephtalate (PBT).

Next, the at least one stopper 160 is formed of a material same as that of the package housing 150 and is higher by a certain height that the exposed surface A of the substrates 121 and 122. Accordingly, the thickness of the heat transfer connectors 171 used to join the heat sinks 170 may be adjusted and thus, the thickness at both ends of the heat transfer connectors 171 may be uniformly and constantly maintained.

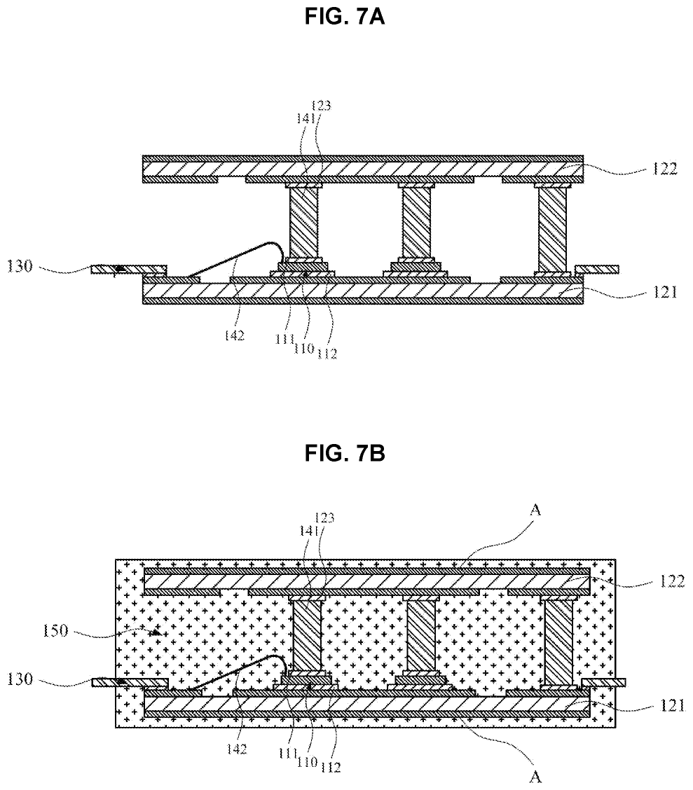

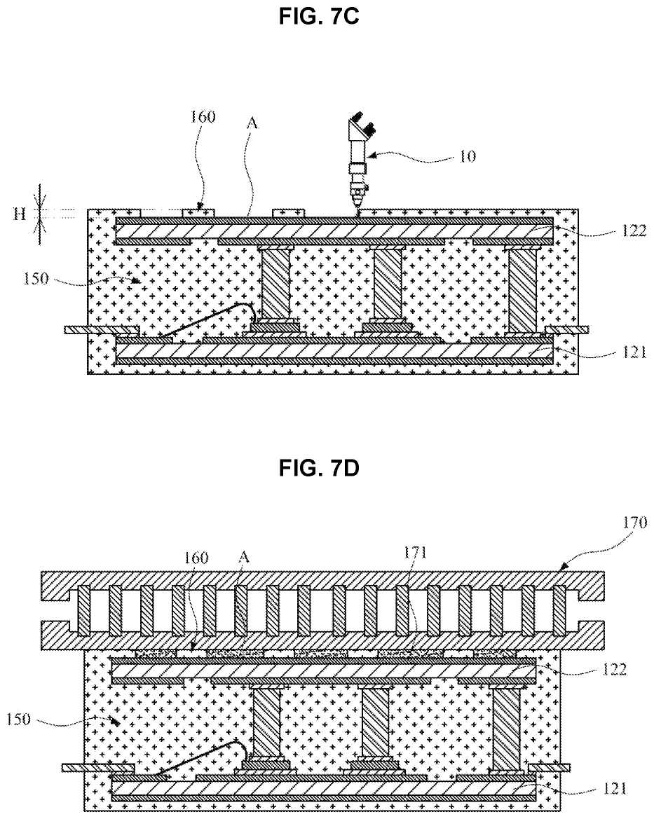

In this regard, as illustrated in FIGS. 7B and 7C, the laser 10 is used to partially engrave the surface of the package housing 150 while the package housing 150 covers the substrates 121 and 122 by a certain height and then, the at least one stopper 160 may be formed. As mentioned in the embodiment above, the stopper 160 may be overlapped with the exposed surface A of the substrates 121 and 122 or as mentioned in another embodiment above, the stopper 160 may not be overlapped with the exposed surface A of the substrates 121.

That is, FIG. 3 illustrates a structure of the stoppers 160 on the upper part of the substrate included in the semiconductor package of FIG. 2 according to an embodiment of the present invention and FIG. 4 illustrates a structure of the stoppers 160 on the upper part of the substrate included in the semiconductor package of FIG. 2 according to another embodiment of the present invention.

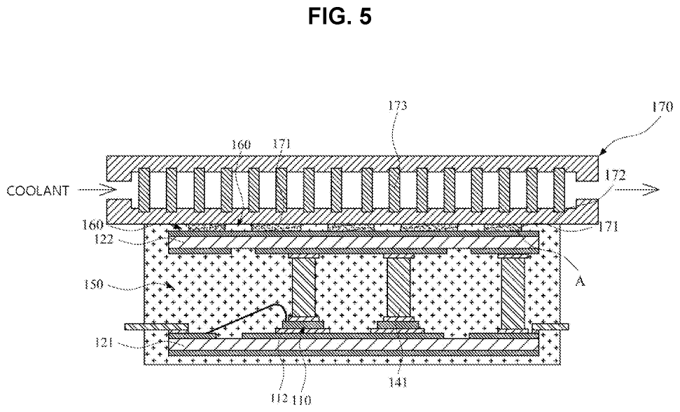

More specifically, referring to FIGS. 3 and 5, the stoppers 160 on the upper parts of the substrates 121 and 122 according to an embodiment of the present invention may be disposed on the exposed surfaces A of the substrates 121 and 122 or cover at least a part of the exposed surfaces A. Accordingly, a contact area between the stopper 160 and the heat transfer connector 171 is enlarged so that delamination of the heat transfer connector 171 may be suppressed and adhesive strength to the heat sink 170 may be improved. Also, heat conduction may be constantly accomplished to the heat sink 170 through the heat transfer connector 171 having a uniform thickness.

Also, referring to FIGS. 4 and 5, the stoppers 160 on the upper parts of the substrates 121 and 122 according to another embodiment of the present invention are not overlapped with the exposed surface A of the substrates 121 and 122. Accordingly, a contact area between the stopper 160 and the heat transfer connector 171 is enlarged so that delamination of the heat transfer connector 171 may be suppressed and adhesive strength to the heat sink 170 may be improved. Also, heat conduction may be constantly accomplished to the heat sink 170 through the heat transfer connector 171 having a uniform thickness.

The height H of the stoppers 160, as illustrated in FIGS. 3 and 4, may be equally 1 μm through 1 mm and the stoppers 160 may be formed to be high in the form of at least any one plane including a circle, a quadrangle, and a polygon.

Also, the height H of the at least one stopper 160 may be determined by the partial surface of the package housing 150 which is not engraved by the laser 10. That is, the height H of the stopper 160 may be determined as a height from the exposed surface A of the substrates 121 and 122 to the partial surface of the package housing 150 which is not engraved.

In addition, as illustrated in FIG. 5, the at least one semiconductor chip 110 may be structurally connected to one surface of the lower substrate 121 by using an adhesive 112, the stoppers 160 may not be formed on the other surface of the lower substrate 121, the at least one stopper 160 may be formed on one surface of the upper substrate 122, and the other surface of the upper substrate 122 may be electrically connected to the semiconductor chips 110 through the spacers 141 which are the electrical connectors.

As illustrated in FIG. 2, the at least one semiconductor chip 110 may be structurally connected to one surface of the lower substrate 121 by using the adhesive 112, the stoppers 160 may be formed on the other surface of the lower substrate 121, the at least one stopper 160 may be formed on one surface of the upper substrate 122, and the other surface of the upper substrate 122 may be electrically connected to the semiconductor chips 110 through the spacers 141 which are the electrical connectors.

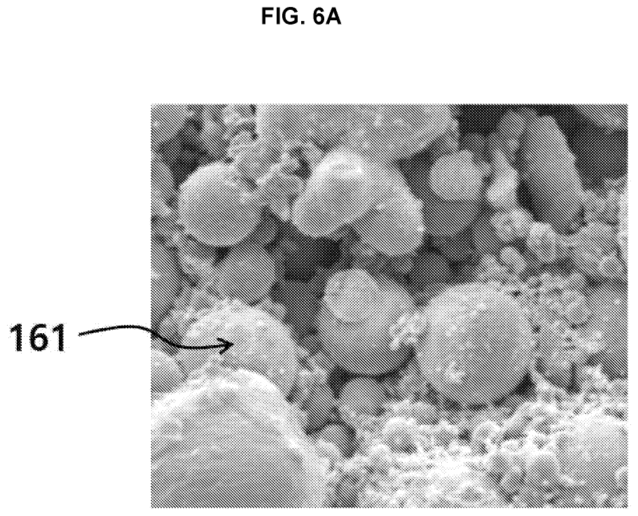

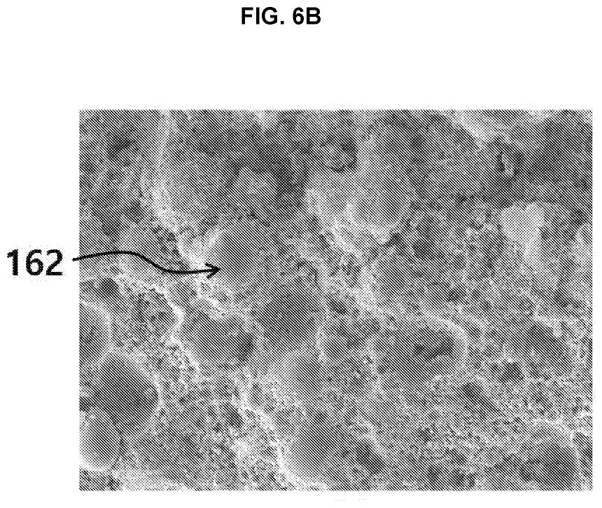

Referring to FIGS. 6A and 6B, at least one spherical grain 161 or at least one round groove 162 may be formed on the wall of the stopper 160 so as to improve adhesive strength with the heat transfer connector 171 and more preferably, the diameter of the grains 161 or the depth of the round grooves 162 may be 1 μm through 100 μm.

Next, the at least one heat sink 170 circulates a coolant so that heat generated from the semiconductor chips 110 is transmitted and radiated.

For example, at least one metal cooling post 173 is arranged in the inner space of the heat sink 170 in the flow direction of the coolant so that heat generated from the semiconductor package may be efficiently radiated by the coolant which directly contacts the metal cooling posts 173.

Here, as illustrated in FIG. 5, one surface 172 of the heat sink 170 may be at least one metal layer or at least one ceramic layer, and the thickness of the heat transfer connector 171 interposed between one surface 172 of the heat sink 170 and the exposed surface A of the at least one substrate 121 and 122 may correspond to the height H of the stopper 160 which is 1 μm through 1 mm.

Thermal conductivity of the heat transfer connector 171 may be 1 W/m-k through 400 W/m-k.

The heat transfer connectors 171 may be filled by 60% or more and trapped in the stoppers 160, the exposed surfaces A of the substrates 121 and 122, and the one surfaces 172 of the heat sinks 170.

Accordingly, at least a part of the exposed surface A of one or more substrates 121 and 122 is formed on the upper surface, the lower surface, or the upper and lower surfaces of the package housing 150, and the exposed surface A of one or more substrates 121 and 122 is joined to the heat sink 170 by using the heat transfer connector 171 interposed therebetween. Accordingly, the full thickness of the heat transfer connectors 171 may be uniformly maintained by the stoppers 160.

FIGS. 7A, 7B, 7C and 7D illustrate a method of manufacturing a semiconductor package having a package housing in an engraved surface form according to another embodiment of the present invention. Referring to FIGS. 7A, 7B, 7C and 7D, the method includes (a) preparing the lower substrate 121 and the upper substrate 122 to which the at least one semiconductor chip 110 is to be installed, the electrical connectors 141 and 142, and the at least one terminal lead 130 and structurally connecting the lower substrate 121, the upper substrate 122, the semiconductor chips 110, and the electrical connectors 141 and 142 using the adhesives 111, 112, and 123(FIG. 7A), (b) forming the package housing 150 to cover the semiconductor chips 110, the electrical connectors 141 and 142, the entire surfaces of the lower and upper substrates 121 and 122 being installed, and at least a part of the exposed surfaces A of the lower and upper substrates 121 and 122(FIG. 7B), and (c) partially engraving the surface of the package housing 160 by using the laser 10 to form the stoppers 160 to be higher by a certain height than the exposed surface A of the lower substrate 121 or the upper substrate 122(FIG. 7C).

Here, the height H of the stoppers 160 may be 1 μm through 1 mm and the thickness of the heat transfer connectors 171 used to join the heat sinks 170 may be adjusted by the stoppers 160. Accordingly, the thickness at both ends of the heat transfer connectors 171 may be uniformly and constantly maintained.

Referring to FIG. 7D, the at least a part of the exposed surface A of one or more substrates 121 and 122 is formed on the upper surface, the lower surface, or the upper and lower surfaces of the package housing 150, and the exposed surface A of one or more substrates 121 and 122 is joined to the heat sink 170 by using the heat transfer connector 171 interposed therebetween. Accordingly, the full thickness of the heat transfer connector 171 may be uniformly maintained.

In the semiconductor package having a package housing in an engraved surface form and the method of manufacturing the same as described above, the thickness of the heat transfer connector used to join and transfer heat to the heat sink may be adjusted through the stopper, which is engraved using the laser, and uniformly maintained to suppress delamination and to improve heat transfer efficiency. Also, compared with the conventional stopper structure using the grinding wheel and the method of manufacturing the same, consumption of the sealing member used for molding the package housing may be minimized, cracks of ceramic used to form an insulating layer of the substrate may be prevented, the thickness of the metal layer having the exposed surfaces of the substrate may be minimized, abnormal insulation voltage occurring due to metal particles generated while grinding which remain between the package housing may be blocked, and stress on the semiconductor package may be minimized to prevent delamination.

According to the present invention, the thickness of the heat transfer connector used to join and transfer heat to the heat sink may be adjusted through the stopper, which is engraved using the laser, and uniformly maintained to suppress delamination and to improve heat transfer efficiency

Also, compared with the conventional stopper structure using the grinding wheel and the method of manufacturing the same, consumption of the sealing member used for molding the package housing may be minimized, cracks of ceramic used to form an insulating layer of the substrate may be prevented, the thickness of the metal layer having the exposed surfaces of the substrate may be minimized, abnormal insulation voltage occurring due to metal particles generated while grinding which remain between the package housing may be blocked, and stress on the semiconductor package may be minimized to prevent delamination.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package having a package housing in an engraved surface form comprising:
at least one substrate on which at least one semiconductor chip is installed;
at least one terminal lead electrically connected to the substrates;
electrical connectors for connecting the semiconductor chips to the substrates or the terminal leads;
a package housing covering the semiconductor chips, the electrical connectors, and the at least one substrate;
at least one stopper which is formed of a material same as that of the package housing, is higher by a certain height than exposed surfaces of the substrates, is disposed on the exposed surfaces of the substrates, or covers at least a part of the exposed surfaces; and
at least one heat sink transmitting heat from the semiconductor chips and radiating heat, wherein the at least a part of the exposed surfaces of the at least one substrate is formed on the upper surface, the lower surface, or the upper and lower surfaces of the package housing and the exposed surfaces of the at least one substrate are joined to the heat sinks by using heat transfer connectors interposed therebetween.

2. The semiconductor package of claim 1, wherein the substrates are metal substrates or comprise at least one insulating layer.

3. The semiconductor package of claim 1, wherein the height of the stoppers is 1 μm through 1 mm.

4. The semiconductor package of claim 1, wherein the stoppers are formed to be high in the form of at least any one plane including a circle, a quadrangle, and a polygon.

5. The semiconductor package of claim 1, wherein the at least one stopper is formed by partially engraving the surface of the package housing using a laser.

6. The semiconductor package of claim 1, wherein the height of the at least one stopper is determined by the partial surface of the package housing which is not engraved.

7. The semiconductor package of claim 1, wherein the electrical connectors are conductive spacers in a hexahedral or a cylindrical form.

8. The semiconductor package of claim 7, wherein one side of the spacer is electrically joined to the semiconductor chip on a first substrate using a conductive adhesive and the other side of the spacer is electrically joined to a second substrate using a conductive adhesive.

9. The semiconductor package of claim 1, wherein the electrical connectors are electrically connected between the at least one semiconductor chip and the substrates.

10. The semiconductor package of claim 1, wherein the semiconductor chips are installed on an upper substrate or a lower substrate.

11. The semiconductor package of claim 1, wherein the stoppers comprise at least one spherical grain or at least one round groove on the wall thereof.

12. The semiconductor package of claim 11, wherein the diameter of the grains or the depth of the round grooves is 1 μm through 100 μm.

13. The semiconductor package of claim 1, wherein the heat sink comprises at least one metal layer or at least one ceramic layer on one surface thereof.

14. The semiconductor package of claim 1, wherein the thickness of the heat transfer connector interposed between one surface of the heat sink and the exposed surface of the at least one substrate is 1 μm through 1 mm.

15. The semiconductor package of claim 14, wherein the heat transfer connector has thermal conductivity of 1 W/m-k through 400 W/m-k.

16. The semiconductor package of claim 1, wherein the heat transfer connectors are trapped by 60% or more in the stoppers, the exposed surfaces of the substrates, and the one surfaces of the heat sinks.

17. The semiconductor package of claim 1, wherein the at least one semiconductor chip is structurally connected to one surface of the lower substrate by using an adhesive, the at least one stopper is not formed on the other surface of the lower substrate, the at least one stopper is formed on one surface of the upper substrate, and the other surface of the upper substrate is electrically connected to the semiconductor chips through the electrical connectors.

18. The semiconductor package of claim 1, wherein the at least one semiconductor chip is structurally connected to one surface of the lower substrate by using an adhesive, the at least one stopper is formed on the other surface of the lower substrate, the at least one stopper is formed on one surface of the upper substrate, and the other surface of the upper substrate is electrically connected to the semiconductor chips through the electrical connectors.

19. A semiconductor package having a package housing in an engraved surface form comprising:
at least one substrate on which at least one semiconductor chip is installed;
at least one terminal lead electrically connected to the substrates;
electrical connectors for connecting the semiconductor chips to the substrates or the terminal leads;
a package housing covering the semiconductor chips, the electrical connectors, and the at least one substrate;
at least one stopper which is formed of a material same as that of the package housing, is higher by a certain height than exposed surfaces of the substrates, and is not overlapped with the exposed surfaces of the substrates; and
at least one heat sink transmitting heat from the semiconductor chips and radiating heat, wherein the at least a part of the exposed surfaces of the at least one substrate is formed on the upper surface, the lower surface, or the upper and lower surfaces of the package housing and the exposed surfaces of the at least one substrate are joined to the heat sinks by using heat transfer connectors interposed therebetween.

20. A method of manufacturing a semiconductor package having a package housing in an engraved surface form comprising:
preparing a lower substrate and an upper substrate to which at least one semiconductor chip is to be installed, electrical connectors, and at least one terminal lead;
structurally connecting the lower substrate, the upper substrate, the semiconductor chips, and the electrical connectors by using conductive adhesives;
forming a package housing to cover the semiconductor chips, the electrical connectors, the entire surfaces of the lower and upper substrates being installed, and at least a part of the exposed surfaces of the lower substrate and the upper substrate;
partially engraving the surface of the package housing by using a laser to form stoppers to be higher by a certain height than exposed surfaces of the lower substrate or the upper substrate; and
joining the exposed surfaces of the at least one substrate to heat sinks by using heat transfer connectors.
